(19) United States
(12) Patent Application Publication
(10) Pub. No.: US 2015/0200636 A1
(43) Pub. Date: Jul. 16, 2015

(54) AMPLIFIER CIRCUIT, A/D CONVERTER, AND COMMUNICATION APPARATUS

(71) Applicant: KABUSHIKI KAISHA TOSHIBA, Minato-ku (JP)

(72) Inventors: Junya Matsuno, Kawasaki (JP); Masanori Furuta, Odawara (JP); Tetsuro Itakura, Nerima (JP)

(73) Assignee: KABUSHIKI KAISHA TOSHIBA, Minato-ku (JP)

(21) Appl. No.: 14/592,116

(22) Filed: Jan. 8, 2015

(30) Foreign Application Priority Data
Jan. 14, 2014 (JP) 2014-004135

(51) Int. Cl. H03F 3/72; H03M 1/00; H03M 1/16; H03F 3/45

(52) U.S. Cl. CPC H03F 3/72; H03F 3/45071; H03M 1/002; H03M 1/164; H03F 2203/7221; H03F 2203/45226; H03F 2203/45206

(57) ABSTRACT

An amplifier circuit according to one embodiment includes an input terminal, an output terminal, an amplifier, a first switch, and a first signal setter. An input side of the amplifier is connected to the input terminal and an output side is connected to the output terminal. A difference between a signal input from the input side and a predetermined reference signal is amplified with a predetermined gain. The first switch opens and closes between the output side of the amplifier and the output terminal. The first signal setter sets a signal of the output terminal to the predetermined signal when the first switch opens.

### CROSS REFERENCE TO RELATED APPLICATION(S)

This application is based upon and claims the benefit of priority from the prior Japanese Patent Application No. 2014-004135, filed on Jan. 14, 2014, the entire contents of which are incorporated herein by reference.

### FIELD

Embodiments described herein relate generally to an amplifier circuit, an A/D converter, and a communication apparatus.

### BACKGROUND

A pipeline A/D converter is employed in a number of LSI products as an architecture which can achieve both high speed and high resolution. A traditional pipeline A/D converter has sometimes used an operational amplifier to perform pipeline operation. However, there has been a problem in that power consumption of the pipeline A/D converter becomes larger because the power consumption of the operational amplifier is large. A technique is proposed in which the power consumption of the pipeline A/D converter is reduced by using a low power consumption amplifier circuit and switch instead of a large power consumption operational amplifier.

In the pipeline A/D converter for using the amplifier circuit and the switch, an input signal is amplified by the amplifier circuit, and pipeline operation is performed by opening/closing (OFF/ON) the switch according to the amplified signal. The pipeline operation includes an amplification phase and a reset phase in a case where the operation of the amplifier circuit has been focused on. In the amplification phase, the amplifier circuit amplifies and outputs an input signal. On the other hand, in the reset phase, the amplifier circuit outputs a predetermined reset signal which turns OFF the switch. Therefore, when the reset phase transitions to the amplification phase, an output signal of the amplifier circuit transitions from the reset signal to an amplified input signal. In such a pipeline A/D converter, when the operation of the amplifier circuit in a case where the reset phase transitions to the amplification phase, that is, transition of a signal is delayed, there has been a possibility that signal processing at a subsequent stage is not accurately performed.

### BRIEF DESCRIPTION OF THE DRAWINGS

FIG. 1 is a block diagram of an amplifier circuit according to a first embodiment;

FIG. 2 is a block diagram of a zero cross detector having the amplifier circuit in FIG. 1;

FIG. 3 is a timing chart of operation of the zero cross detector in FIG. 2;

FIGS. 4A and 4B are explanatory diagrams of a zero cross detector having a traditional amplifier circuit;

FIG. 5 is a block diagram of an amplifier circuit according to a second embodiment;

FIG. 6 is a block diagram of another example of the amplifier circuit according to the second embodiment;

FIG. 7 is a block diagram of still another example of the amplifier circuit according to the second embodiment;

FIG. 8 is a block diagram of an amplifier circuit according to a third embodiment;

FIG. 9 is a block diagram of an amplifier circuit according to a fourth embodiment;

FIG. 10 is a block diagram of an A/D converter according to a fifth embodiment; and

FIG. 11 is a block diagram of a function of a communication apparatus according to a sixth embodiment.

### DETAILED DESCRIPTION

Embodiments will now be explained with reference to the accompanying drawings. The present invention is not limited to the embodiments.

An amplifier circuit according to one embodiment includes an input terminal, an output terminal, an amplifier, a first switch, and a first signal setter. An input side of the amplifier is connected to the input terminal and an output side is connected to the output terminal. A difference between a signal input from the input side and a predetermined reference signal is amplified with a predetermined gain. The first switch opens and closes between the output side of the amplifier and the output terminal. The first signal setter sets a signal of the output terminal to the predetermined signal when the first switch opens.

The amplifier circuit, the A/D converter, and the communication apparatus according to the embodiments will be described below with reference to the drawings.

### First Embodiment

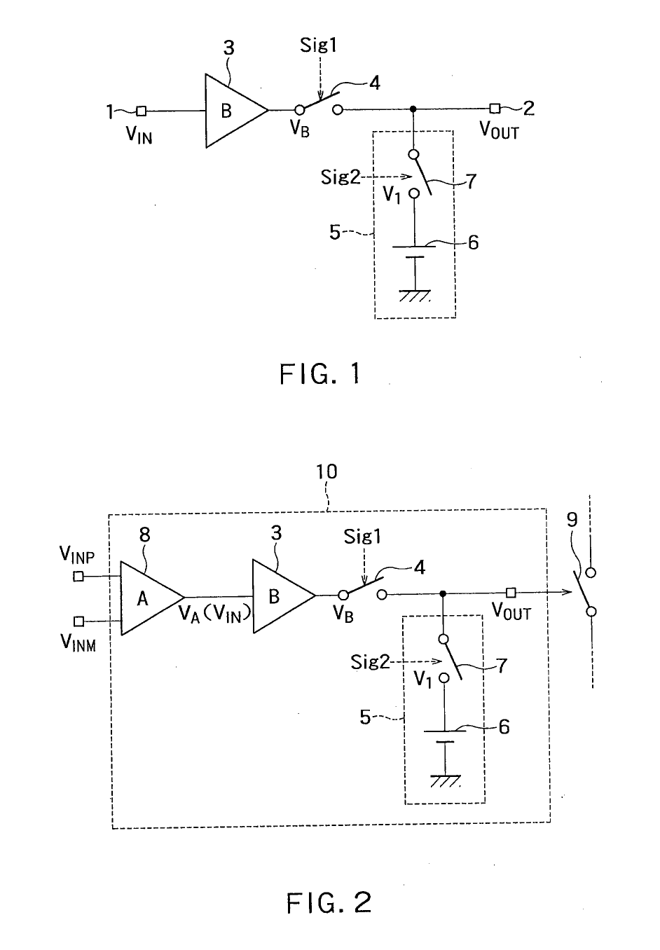

First, an amplifier circuit according to the first embodiment will be described with reference to FIGS. 1 to 4. FIG. 1 is a block diagram of the amplifier circuit according to the present embodiment. The amplifier circuit includes an input terminal 1, an output terminal 2, an amplifier 3, a switch 4, and a voltage setter 5 as shown in FIG. 1.

An input signal (input voltage) V_{IN} is input from the input terminal 1. An output signal (output voltage) V_{OUT} is output from the output terminal 2.

The amplifier 3 is a single-phase amplifier of a single-phase input and a single-phase output. An input side of the amplifier 3 is connected to the input terminal 1. An output side of the amplifier 3 is connected to the output terminal 2 via the switch 4. The amplifier 3 includes a predetermined reference voltage (reference signal) V_{X} therein. The amplifier 3 amplifies a difference between a signal (voltage) input from the input side and a reference voltage V_{X} with a predetermined gain B and outputs the amplified signal from the output side. It is preferable that the gain B of the amplifier 3 be set to a value in which (V_{IN}−V_{X})×B is large enough ((V_{IN}−V_{X})×B>>V_{HIGH}) or a value in which (V_{IN}−V_{X})×B is small enough ((V_{IN}−V_{X})×B<<V_{LOW}) relative to a voltage range (V_{LOW}<V<V_{HIGH}) which can be taken by the amplifier circuit. The gain B is a positive or negative value and normally set to a significantly large value. The amplifier 3 is realized by an inverter circuit (logic inverter circuit), for example.

By setting the gain B in this way, the signal (voltage) amplified by the amplifier 3 becomes V_{HIGH} or V_{LOW}. For example, in a case where the amplifier 3 is a normal phase amplifier (gain B>>0), the signal amplified by the amplifier 3 (the voltage of the output side of the amplifier 3) V_{B} becomes V_{HIGH} when the input signal (V_{IN}−V_{X}) is larger than zero. Similarly, when the input signal (V_{IN}−V_{X}) is smaller than zero, V_{B} becomes V_{LOW}. Also, when the amplifier 3 is a reversed-phase amplifier (gain B<<0), V_{B} becomes V_{LOW} when the input signal (V_{IN}−V_{X}) is larger than zero, and V_{B} becomes V_{HIGH} when the input signal (V_{IN}−V_{X}) is smaller than zero.

It is assumed below that V_{HIGH} be a power-supply voltage V_{DD} and V_{LOW} be a ground voltage V_{GND}. However, V_{HIGH} and V_{LOW} are not limited to these, and can be arbitrarily set according to a circuit design.

The switch 4 (first switch) is provided between the output side of the amplifier 3 and the output terminal 2. The switch 4 opens/closes (opens and closes) (OFF/ON) between the output side of the amplifier 3 and the output terminal 2. When the switch 4 is ON (close), the output side of the amplifier 3 is connected to the output terminal 2, and then, the a voltage V_{B} of the output side of the amplifier 3 is output from the output terminal 2 as an output voltage V_{OUT}. On the other hand, when the switch 4 is OFF (open), the output side of the amplifier 3 is opened. The switch 4 includes an element such as a transistor, and the opening/closing of the switch 4 is controlled by a control signal Sig1. It is assumed below that when the control signal Sig1 is ON, the switch 4 become ON and when the control signal Sig1 is OFF, the switch 4 become OFF. Another switch and control signal to be described below are similar to the switch 4 and the control signal Sig1.

A voltage setter 5 (first signal setter) sets the output voltage V_{OUT} in a case where the switch 4 is OFF (open) to a predetermined voltage V₁. The voltage setter 5 includes a voltage source 6 and a switch 7.

The voltage source 6 (first signal source) is connected to the output terminal 2 and outputs the predetermined voltage V₁ (first signal) to the output terminal 2. The voltage V₁ output from the voltage source 6 is a constant voltage and is set to a voltage in which a switch 9 to be described below becomes OFF.

The switch 7 (second switch) is provided between the output terminal 2 and the voltage source 6. The switch 7 opens/closes (OFF/ON) between the voltage source 6 and the output terminal 2. When the switch 7 is ON (close), the voltage source 6 is connected to the output terminal 2, and then, the output voltage V₁ of the voltage source 6 is output from the output terminal 2 as the output voltage V_{OUT}. On the other hand, when the switch 7 is OFF (open), the voltage source 6 is opened. The switch 7 includes an element such as a transistor, and the opening/closing of the switch 4 is controlled by a control signal Sig2. The control signal Sig2 is synchronized with the control signal Sig1, and ON/OFF of the control signals Sig 1 and Sig2 are switched. However, ON/OFF of the control signal Sig2 is opposite to that of the control signal Sig1. That is, when the control signal Sig1 becomes ON (OFF), the control signal Sig2 becomes OFF (ON).

A configuration of the voltage setter 5 is not limited to the present embodiment. Configurations can be arbitrarily selected in which the output voltage V_{OUT} in a case where the switch 4 is OFF (open) can be set to a predetermined voltage.

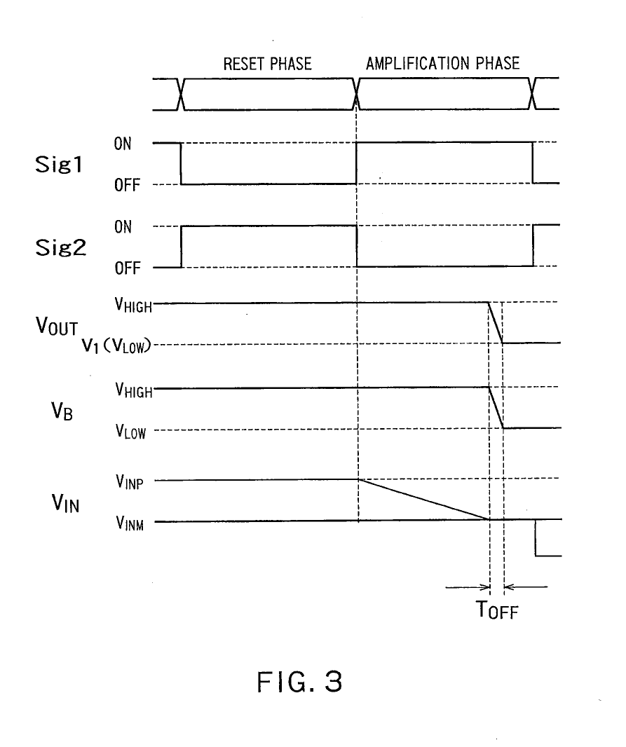

Next, the operation in a case where the amplifier circuit according to the present embodiment is used in the A/D converter will be described with reference to FIGS. 2 and 3. In the A/D converter, the amplifier circuit according to the present embodiment is used to configure a zero cross detector (comparator) 10. FIG. 2 is a block diagram of the zero cross detector 10. As shown in FIG. 2, the zero cross detector 10 includes the amplifier circuit according to the present embodiment and an amplifier 8 of a differential input and the single-phase output.

The amplifier 8 amplifies a difference between an input voltage V_{INP} which is differentially input and an input voltage V_{INM} with a gain A and outputs an output voltage V_{A}. The output voltage V_{A} of the amplifier 8 is input to the amplifier 3 of the amplifier circuit according to the present embodiment as an input voltage V_{IN}. The amplifier 3 amplifies a difference between the input voltage V_{IN} and the reference voltage V_{X} therein with a gain B and outputs an output voltage V_{B}. That is, the output voltage V_{B} is expressed by the following formula.

V_{B}=B×(V_{A}−V_{X})=B×(A×V_{INP}−V_{INM})−V_{X})

The above formula is satisfied in a range of V_{LOW}≦V_{B}≦V_{HIGH}. Here, the gain A is set to a significantly large value similarly to the gain B. Therefore, as described above, an value which is actually taken by the output voltage V_{B} is the maximum voltage V_{HIGH} or the minimum voltage V_{LOW} which can be taken by the zero cross detector 10. Here, A×B>0 satisfied the following formula.

A case of V_{INP}−V_{INM}>0

V_{B}=V_{HIGH}(=power-supply voltage V_{DD})

A case of V_{INP}−V_{INM}≦0

V_{B}=V_{LOW}(=ground voltage V_{GND})

That is, the zero cross detector 10 has a function for determining the magnitudes of the input voltages V_{INP} and V_{INM}. An output voltage (output voltage V_{OUT} of the amplifier circuit according to the present embodiment) of the zero cross detector 10 becomes a signal indicating the above determination result. In the present embodiment, V_{OUT} V_{HIGH} expresses V_{INP}−V_{INM}>0, and V_{OUT}=V_{LOW} expresses V_{INP}−V_{INM}≦0. The output signal V_{OUT} is used as the control signal of the switch 9 as shown in FIG. 2.

When V_{INP}−V_{INM}>0, the switch 9 becomes ON (close), and when V_{INP}−V_{INM}≦0, the switch 9 becomes OFF (open). In a case of the present embodiment, the switch 9 can include an N-channel MOS transistor, for example. The amplifier circuit of the present embodiment is designed such that the switch 9 becomes ON when V_{OUT}=V_{HIGH} and the switch 9 becomes OFF when V_{OUT}=V_{LOW}.

The amplifier 3 may be an amplifier of a reverse phase (gain B<0). In this case, the relationship between V_{HIGH} and V_{LOW} described above becomes opposite. That is, V_{OUT}=V_{HIGH} expresses V_{INP}−V_{INM}≦0, and V_{OUT}=V_{LOW} expresses V_{INP}−V_{INM}>0. Therefore, a switch which becomes ON (close) when V_{OUT}=V_{LOW} and becomes OFF (open) when V_{OUT}=V_{HIGH} may be used as the switch 9. Such a switch 9 can include a P-channel MOS transistor, for example.

The above-mentioned zero cross detector 10 is used in the A/D converter instead of a feedback circuit for using the operational amplifier. In a case where the operation of the amplifier circuit according to the present embodiment is focused on, a feedback system includes the reset phase and the amplification phase. The zero cross detector 10 makes the switch 9 become OFF regardless of the magnitudes of the input voltages V_{INP} and V_{INM} in the reset phase and controls the switch 9 according to the magnitudes of the input voltages V_{INP} and V_{INM} in the amplification phase.

FIG. 3 is a timing chart of operation of the zero cross detector 10 in FIG. 2. A signal in which the voltage decreases/increases with time as a rampwave is assumed as the input voltage V_{INP} in FIG. 3. Also, a signal having a voltage which is substantially constant from a start time point of the reset phase to an end time point of the amplification phase is assumed as the input voltage V_{INM}.

The control signal Sig1 is OFF and the control signal Sig2 is ON in the reset phase as shown in FIG. 3. That is, the switch 4 becomes OFF, and the switch 7 becomes ON. Since the output terminal 2 is connected to the voltage source 6 via the switch 7, the output voltage V₁ of the voltage source 6 is output as the output voltage V_{OUT}. As described above, since the voltage V₁ is set to a voltage in which the switch 9 becomes OFF (for example, V₁=V_{LOW}), the switch 9 in which the V_{OUT} (=V₁=V_{LOW}) is input as the control signal becomes OFF. During the reset phase, since V_{IN}=V_{INP}−V_{INM}>0, the output voltage V_{B} of the amplifier 3 is V_{HIGH}. However, the output voltage V_{B} is not output as the output voltage V_{OUT} because the switch 4 is OFF.

Next, when the reset phase transitions to the amplification phase, the control signal Sig1 becomes ON and the control signal Sig2 becomes OFF. That is, the switch 4 becomes ON, and the switch 7 becomes OFF.

Since the output terminal 2 is connected to the output side of the amplifier 3 by the switch 4, the output voltage V_{OUT} becomes the output voltage V_{B} of the amplifier 3. As described above, since V_{B}=V_{HIGH} is satisfied previously in the reset phase, the output voltage V_{OUT} instantaneously transitions from V₁ (=V_{LOW}) to V_{B} (=V_{HIGH}) when the reset phase transitions to the amplification phase. Transition time at this time is called “ON delay”.

When V_{OUT} becomes V_{HIGH}, the switch 9 becomes ON. In this way, by using the amplifier circuit according to the present embodiment, the operation of the zero cross detector 10 at time of the transition from the reset phase to the amplification phase can be accelerated. That is, the ON delay can be reduced.

After the phase has transitioned to the amplification phase, V_{B} V_{OUT}) decreases to V_{LOW} and the switch 9 becomes OFF when V_{INP} decreases and becomes V_{INP}=V_{INM} (V_{IN}=0). Until V_{B}−V_{OUT}) decreases from V_{HIGH} to V_{LOW}, an OFF delay of the predetermined time T_{OFF} occurs. The delay time T_{OFF} is generated by discharging a parasitic capacitance of the amplifier 3. The delay time T_{OFF} changes according to a time constant determined according to the parasitic capacitance and an output resistance of the amplifier 3. The amplification phase after the switch 9 has become OFF corresponds with a hold phase of the operation of the A/D converter.

As described above, by the amplifier circuit according to the present embodiment, since the output voltage V_{OUT} can be set to the predetermined voltage V₁ by the voltage setter 5 in the reset phase, the switch 9 can be OFF. At the same time, since the space between the output side of the amplifier 3 and the output terminal 2 is opened, the voltage V_{B} of the output side of the amplifier 3 is previously set to V_{HIGH} (or V_{LOW}) during the reset phase. Accordingly, V_{OUT} can transition to V_{HIGH} (or V_{LOW}) at the moment of the transition from the reset phase to the amplification phase. Therefore, the operation of the amplifier circuit (zero cross detector) can be accelerated, and accuracy of the signal processing at the subsequent stage can be improved.

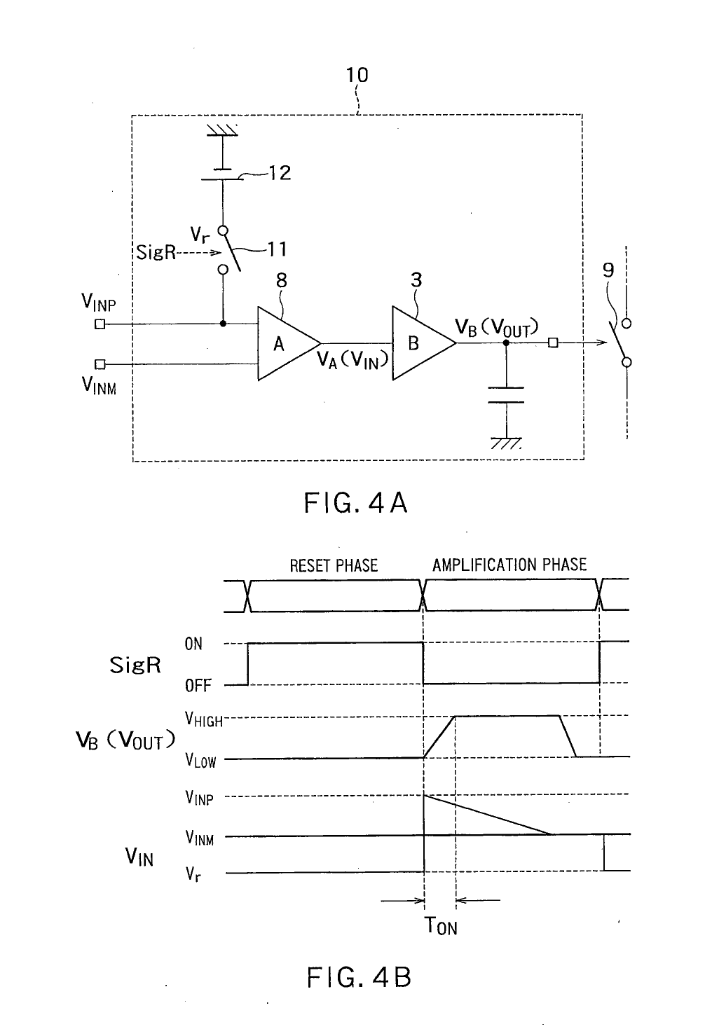

Especially, the amplifier circuit according to the present embodiment does not generate the ON delay which is generated by the zero cross detector 10 using the traditional amplifier circuit in FIG. 4A. In the zero cross detector 10 in FIGS. 4A and 4B, a control signal SigR (switch 11) becomes ON in the reset phase, and a voltage Vᵣ is input from a voltage source 12 to the amplifier 8. The voltage Vᵣ is a voltage (for example, V_{LOW}) in which the voltage V_{B} of the output side of the amplifier 3 allows the switch 9 to be turned OFF. In the zero cross detector 10 in FIGS. 4A and 4B, since V_{B}=V_{OUT} is constantly satisfied, V_{B} (=V_{LOW}) is input to the switch 9 when the control signal SigR becomes ON. Therefore, the switch 9 becomes OFF.

When the reset phase transitions to the amplification phase, the SigR (switch 11) becomes OFF and V_{INP} instead of Vᵣ is input to the amplifier 8. Then, V_{B} (V_{HIGH}) according to the difference between V_{INP} and V_{INM} is output from the amplifier 3 (refer to FIG. 4B). Accordingly, the switch 9 becomes ON. In the traditional amplifier circuit, the ON delay of the predetermined delay time T_{ON} according to the time constant is generated when V_{B} (V_{OUT}) transitions from V_{LOW} to V_{HIGH} as described above. The delay time T_{ON} is the necessary time to charge the parasitic capacitance of the amplifier 3. In FIG. 4A, a parasitic capacitance is schematically illustrated.

By the amplifier circuit according to the present embodiment, since the output side of the amplifier 3 has been previously set to V_{HIGH}, such an ON delay is not generated when the reset phase has transitioned to the amplification phase. Therefore, the delay in the operation of the amplifier circuit can be shortened compared with the traditional amplifier circuit. Also, in the amplifier circuit in FIGS. 4A and 4B, it is necessary to increase drive capability of the amplifier 3 to shorten the ON delay. Therefore, it is necessary to increase the power consumption to shorten the ON delay. On the other hand, since the amplifier circuit according to the present embodiment realizes high-speed operation by having low consumption units such as the switches 4 and 7 and the voltage source 6, the operation of the zero cross detector 10 can be accelerated without increasing the power consumption. Further, since the amplifier circuit according to the present embodiment does not generate the ON delay, duration time of the amplification phase can be shortened for at least the delay time T_{ON} which is generated by the traditional amplifier circuit.

### Second Embodiment

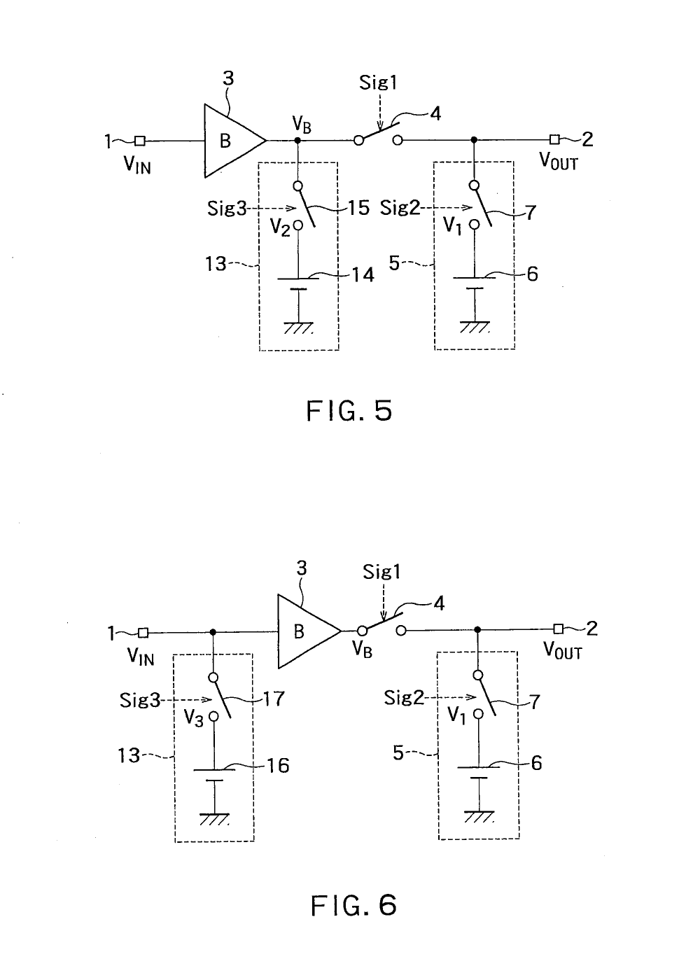

Next, an amplifier circuit according to the second embodiment will be described with reference to FIGS. 5 to 7. FIG. 5 is a block diagram of the amplifier circuit according to the present embodiment. As shown in FIG. 5, the amplifier circuit according to the present embodiment includes an input terminal 1, an output terminal 2, an amplifier 3, a switch 4, and a voltage setter 5. The above configuration is similar to the first embodiment. In the present embodiment, the amplifier circuit further includes a voltage setter 13.

The voltage setter 13 (second signal setter) sets a voltage V_{B} of an output side of the amplifier 3 in a case where the switch 4 is OFF (open) to a predetermined voltage V₂. The voltage setter 13 includes a voltage source 14 and a switch 15 as shown in FIG. 5.

The voltage source 14 (second signal source) is connected to the output side of the amplifier 3 and outputs the voltage V₂ (second signal) to the output side of the amplifier 3. The voltage V₂ output by the voltage source 14 is a constant voltage and is set to a voltage (V_{HIGH}) in which the switch 9 becomes ON. A power-supply voltage V_{DD} may be used as the voltage source 14.

The switch 15 (third switch) is provided between the output side of the amplifier 3 and the voltage source 14 and opens/closes (OFF/ON) between the voltage source 14 and the output side of the amplifier 3. When the switch 15 is ON (close), the voltage source 14 is connected to the output side of the amplifier 3 and the voltage V_{B} of the output side of the amplifier 3 becomes the output voltage V₂ of the voltage source 14. On the other hand, when switch 15 is OFF (open), the voltage source 14 is opened. The switch 15 includes an element such as a transistor, and the opening/closing of the switch 15 is controlled by a control signal Sig3. The control signal Sig3 is synchronized with the control signal Sig2. That is, ON/OFF of the control signal Sig3 coincides with ON/OFF of the control signal Sig2. Accordingly, the switch 15 becomes ON in the reset phase. Therefore, the voltage V_{B} is set to the predetermined voltage V₂ (V_{HIGH}) in the reset phase. The control signal Sig2 can be used as the control signal Sig3.

With the above configuration, the output voltage V_{B} of the amplifier 3 in the reset phase can be set to an arbitrary voltage V₂ by the amplifier circuit according to the present embodiment. By setting V_{B} V₂=V_{HIGH}, V_{OUT} can transition to V_{HIGH} at the moment of the transition from the reset phase to the amplification phase. Accordingly, the operation similar to that of the first embodiment described in FIG. 2 can be realized even when the amplifier 3 cannot amplify the input signal V_{IN} to V_{HIGH} and V_{LOW} because the input voltage V_{IN} is small or the gain B of the amplifier 3 is small.

FIG. 6 is a block diagram of another example of the voltage setter 13. In the present embodiment, the voltage setter 13 is provided on the input side of the amplifier 3. The voltage setter 13 includes a voltage source 16 and a switch 17 as shown in FIG. 6.

The voltage source 16 (third signal source) is connected to the input side of the amplifier 3 and inputs a voltage V₃ (third signal) to the input side of the amplifier 3. The voltage V₃ is a constant voltage and is set so that the voltage V_{B} of the output side of the amplifier 3 becomes the above-mentioned voltage V₂.

The switch 17 (fourth switch) is provided between the input side of the amplifier 3 and the voltage source 16 and opens/closes (OFF/ON) between the voltage source 16 and the input side of the amplifier 3. When the switch 17 is ON (close), the voltage source 16 is connected to the input side of the amplifier 3 and the output voltage V₃ of the voltage source 16 is input to the amplifier 3. Accordingly, the voltage V_{B} of the output side of the amplifier 3 becomes V₂. On the other hand, when the switch 17 is OFF (open), the voltage source 16 is opened. Other configurations are similar to those of the above-mentioned switch 15.

In a case of this configuration, an in-phase (B>0) amplifier can be used as the amplifier 3, and the power-supply voltage V_{DD} can be used as the voltage source 16. Alternatively, a reversed-phase (B<0) amplifier can be used as the amplifier 3, and a ground voltage V_{GND} can be used as the voltage source 16. With either configuration, the operation similar to that of the first embodiment described in FIG. 2 can be realized.

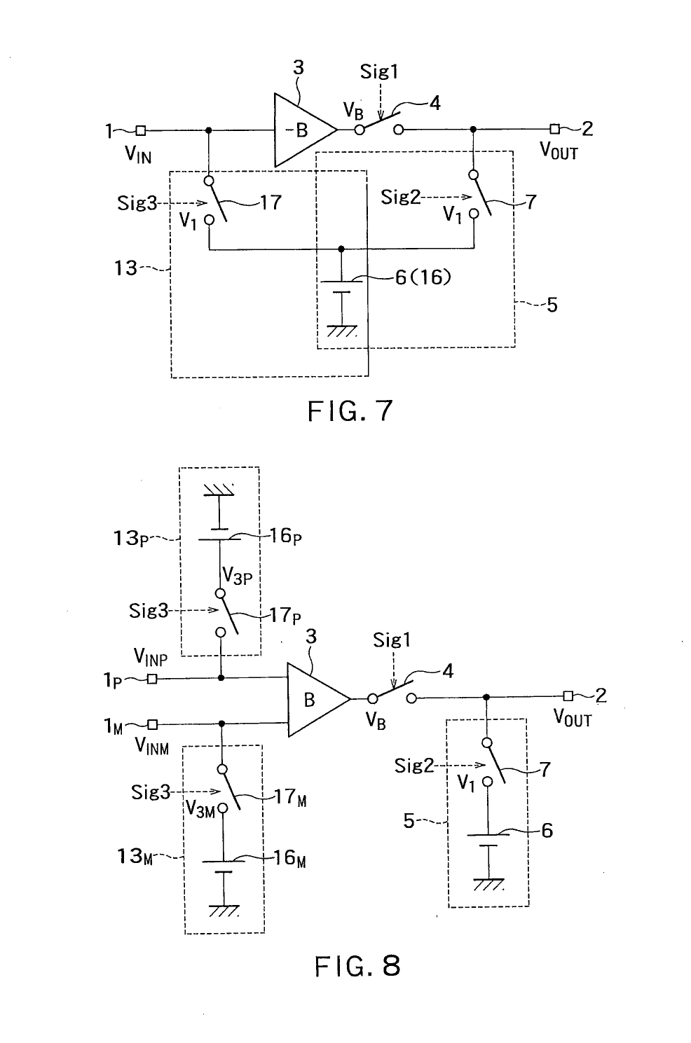

FIG. 7 is a block diagram of another example of the voltage setter 13. As shown in FIG. 7, the voltage source 16 of the voltage setter 13 and the voltage source 6 of the voltage setter 5 are shared, and the reversed-phase (B<0) amplifier is used as the amplifier 3.

In the present embodiment, for example, when it is assumed that the voltage V₁ of the voltage source 6 be the ground voltage V_{GND}, V_{OUT} is V₁=V_{GND}=V_{LOW} output from the voltage source 6 in the reset phase. Also, in the amplification phase, V_{OUT} is V_{B} (V_{HIGH}) in which the V₁ (V_{GND}) input from the voltage source 6 is amplified by the reverse phase. Therefore, the operation similar to that of the first embodiment which has been described in FIG. 2 can be realized. Also, with this configuration, one voltage source can be reduced, and the configuration of the amplifier circuit can be simplified.

The configuration of the voltage setter 13 is not limited to the above when the output voltage V_{B} in a case where the switch 4 is OFF (open) can be set to the predetermined voltage V₂.

### Third Embodiment

Next, an amplifier circuit according to the third embodiment will be described with reference to FIG. 8. FIG. 8 is a block diagram of the amplifier circuit according to the present embodiment. In the present embodiment, an amplifier 3 is a differential amplifier of a differential input and a single-phase output. As shown in FIG. 8, the amplifier circuit according to the present embodiment includes an output terminal 2, the amplifier 3, a switch 4, and a voltage setter 5. The above configuration is similar to that of the first embodiment. In the present embodiment, the amplifier circuit further includes input terminals 1_{P} and 1_{M} and voltage setters 13_{P} and 13_{M}.

Input signals V_{INP} and V_{INM} are respectively input to the input terminals 1_{P} and 1_{M}. The amplifier 3 amplifies and outputs a difference between V_{INP} and V_{INM} respectively input from the input terminals 1_{P} and 1_{M} in an amplification phase. The amplifier circuit according to the present embodiment can be used as the zero cross detector 10 which has been described in FIG. 2.

The voltage setters 13_{P} and 13_{M} (second signal setters) set voltages of an input side of the amplifier 3 to predetermined voltages V_{3P} and V_{3M} so as to set a voltage V_{B} of the output side of the amplifier 3 to a predetermined voltage V₂ in a case where the switch 4 is OFF(open). As shown in FIG. 8, the voltage setter 13_{P} is connected to one line (side of the input terminal 1_{P}) of the input side of the amplifier 3, and the voltage setter 13_{M} is connected to another line (side of the input terminal 1_{M}) of the input side.

The voltage setter 13_{P} includes a voltage source 16_{P} (fourth signal source) for outputting a voltage V_{3P} (fourth signal) and a switch 17_{P} (fifth switch) in which opening/closing of the switch 17_{P} is controlled by a control signal Sig3. Also, the voltage setter 13_{M} includes a voltage source 16_{M} (fifth signal source) for outputting a voltage V_{3M} (fifth signal) and a switch 17_{M} (sixth switch) in which the opening/closing of the switch 17_{M} is controlled by a control signal Sig3.

The voltages V_{3P} and V_{3M} are the voltages in which a difference therebetween is amplified by the amplifier 3 so that the voltage V_{B} of the output side of the amplifier 3 becomes the voltage V₂. The voltage V₂ is a voltage V_{HIGH} which turns ON the switch 9 as described above. Therefore, the voltages V_{3P} and V_{3M} are set so as to satisfy V_{3P}>V_{3M}. Other configurations of the voltage setters 13_{P} and 13_{M} are similar to those of the voltage setter 13 in FIG. 6.

As described above, since the control signals Sig2 and Sig3 are synchronized with each other, the opening/closing of the switches 7, 17_{P}, and 17_{M} are synchronized with one another. Accordingly, the switches 7, 17_{P}, and 17_{M} become ON and the switch 4 becomes OFF in the reset phase. The switch 7 becomes ON so that V₁ (V_{LOW}) is output as V_{OUT}. Also, the switches 17_{P} and 17_{M} become ON so that the voltages V_{3P} and V_{3M} are input to the amplifier 3, and then, the voltage V_{B} of the output side of the amplifier 3 becomes V_{HIGH}.

Also, the switches 7, 17_{P}, and 17_{M} become OFF and the switch 4 becomes ON in the amplification phase. Accordingly, V_{B} in which a difference between V_{INP} and V_{INM} is amplified is output as V_{OUT}. Therefore, the operation similar to that of the first embodiment which has been described in FIG. 2 can be realized.

In the present embodiment, when one of V_{INP} or V_{INM} is known, a configuration is available in which a voltage setter which is provided on a side where the known voltage is input can be omitted. For example, when V_{INP} is known, it is preferable to omit the voltage setter 13_{P} and set the voltage of the input side of the amplifier 3 to a lower voltage than V_{INP} by the voltage setter 13_{M}. Conversely, when V_{INM} is known, it is preferable to omit the voltage setter 13_{M} and set the voltage of the input side of the amplifier 3 to a higher voltage than V_{INM} by the voltage setter 13_{P}. Accordingly, the voltage V_{B} of the output side of the amplifier 3 in the reset phase can be set to V_{HIGH}.

### Fourth Embodiment

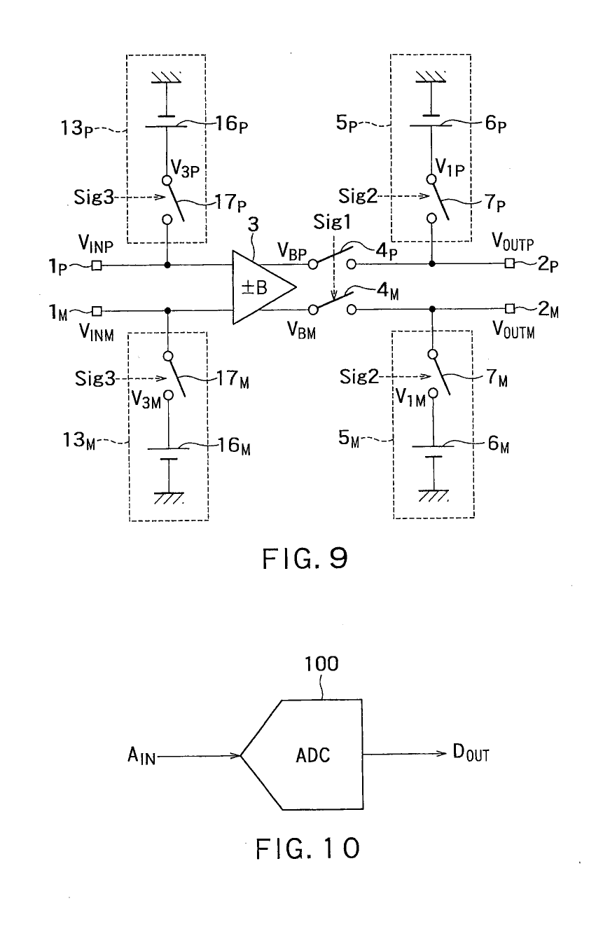

Next, an amplifier circuit according to the fourth embodiment will be described with reference to FIG. 9. FIG. 9 is a block diagram of the amplifier circuit according to the present embodiment. An amplifier 3 of the present embodiment is a fully differential amplifier of a differential input and a differential output. As shown in FIG. 9, the amplifier circuit according to the present embodiment includes input terminals 1_{P} and 1_{M}, the amplifier 3, and voltage setters 13_{P} and 13_{M}. The above configuration is similar to that of the third embodiment. In the present embodiment, the amplifier circuit further includes output terminals 2_{P} and 2_{M}, switches 4_{P} and 4_{M}, and voltage setters 5_{P} and 5_{M}.

The output terminals 2_{P} and 2_{M} respectively output output signals V_{OUTP} and V_{OUTM}. The amplifier 3 amplifies a difference between V_{INP} and V_{INM} respectively input from the input terminals 1_{P} and 1_{M} with the normal phase (B>0) and outputs it from the output terminal 2_{P} in the amplification phase. Also, the amplifier 3 amplifies a difference between V_{INP} and V_{INM} respectively input from the input terminals 1_{P} and 1_{M} with a reversed-phase (B<0) and outputs it from the output terminal 2_{M} in the amplification phase. With this configuration, the amplifier circuit according to the present embodiment can be used as a fully differential zero cross detector.

The voltage setters 5_{P} and 5_{M} (first signal setters) respectively set the output voltages V_{OUTP} and V_{OUTM} in a case where the switches 4_{P} and 4_{M} are OFF (open) to predetermined voltages V_{1P} and V_{1M}. As shown in FIG. 8, the voltage setters 5_{P} and 5_{M} are respectively connected to the output terminals 2_{P} and 2_{M}.

The voltage setter 5_{P} includes a voltage source 6_{P} (sixth signal source) for outputting the voltage V_{1P} (sixth signal) and the switch 4_{P} (seventh switch) in which opening/closing of the switch 4_{P} is controlled by a control signal Sig1. Also, the voltage setter 5_{M} includes a voltage source 6_{M} (seventh signal source) for outputting the voltage V_{1M} (seventh signal) and the switch 4_{M} (eighth switch) in which opening/closing of the switch 4_{M} is controlled by the control signal Sig1. The configurations of the voltage setters 5_{P} and 5_{M} described above are similar to the configuration of the voltage setter 5 in FIG. 1.

In the present embodiment, the amplifier circuit operates such that voltages V_{BP} and V_{BM} of the output side of the amplifier 3 become reverse phase. That is, the output voltages V_{BP} and V_{BM} are expressed by the following formula.

(a case of V_{INP}−V_{INM}>0)

V_{BP}=V_{HIGH}

V_{BM}=V_{LOW}

(a case of V_{INP}−V_{INM}≦0)

V_{BP}=V_{LOW}

V_{BM}=V_{HIGH}

When the output terminal 2_{P} is focused on, the operation of the amplifier circuit is similar to that of the amplifier circuit according to the third embodiment in a case where the amplifier 3 is a normal phase (B>0). Also, when the output terminal 2_{M} is focused on, the operation of the amplifier circuit is similar to that of the amplifier circuit according to the third embodiment in a case where the amplifier 3 is the reversed-phase (B<0). Therefore, the amplifier circuit according to the present embodiment can obtain the similar effect to the third embodiment. Also, a fully differential zero cross detector can be configured by using the amplifier circuit according to the present embodiment.

### Fifth Embodiment

Next, an A/D converter including the amplifier circuit according to the embodiments described above will be described as the fifth embodiment with reference to FIG. 10. FIG. 10 is a block diagram of an A/D converter 100 according to the present embodiment. In the present embodiment, when an analog signal A_{IN} is input to the A/D converter 100, the analog signal A_{IN} is sampled at predetermined sampling intervals. The sampled signal is input as the input signal V_{IN} to the zero cross detector 10 including the above-mentioned amplifier circuit.

The A/D converter according to the present embodiment can be applied to an existing arbitrary A/D converter for using a zero cross detector. Since the A/D converter according to the present embodiment uses the amplifier circuit according to the embodiments described above, a signal input by a switch 9 can be performed at high speed. Therefore, the operation of the amplifier circuit can prevent loss of the signal input caused by the delay, and the accuracy of the signal processing at the subsequent stage can be improved. Also, the power consumption to accelerate the operation of the amplifier circuit can be reduced.

Especially, it is preferable to apply the A/D converter according to the present embodiment to a pipeline A/D converter. In the pipeline A/D converter, since the zero cross detectors of the number of pipeline stages are used, the amplifier circuit according to the embodiments described above can be used as each zero cross detector. Accordingly, the above-mentioned effect can be obtained relative to each zero cross detector, and a remarkable effect can be obtained on the whole.

Also, since the amplifier circuit according to the embodiments described above can shorten duration time of the amplification phase, the sampling interval can be shortened. Therefore, A/D conversion processing by the A/D converter can be performed at higher speed.

### Sixth Embodiment

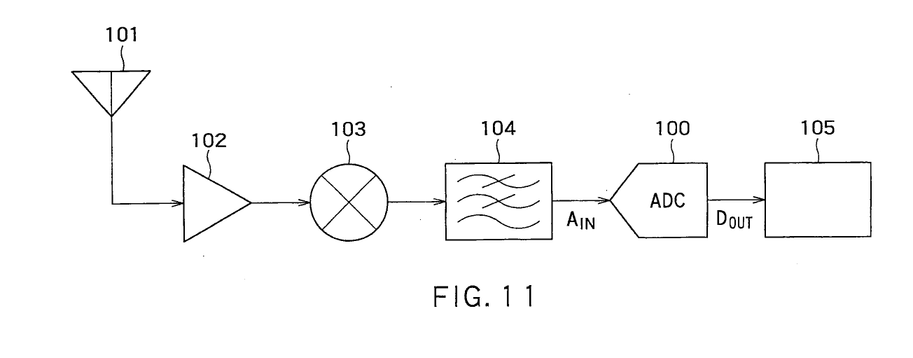

Next, a communication apparatus having the A/D converter 100 according to the fifth embodiment will be described as the sixth embodiment with reference to FIG. 11. FIG. 11 is a block diagram of a function of the communication apparatus according to the present embodiment. The communication apparatus includes an antenna 101, a signal amplifier circuit 102, a frequency conversion circuit 103, a filter circuit 104, an A/D converter 100, and a digital signal processor 105.

In the present embodiment, an analog signal received by the antenna 101 is amplified by the amplifier circuit 102. An arbitrary amplifier circuit can be used as the signal amplifier circuit 102. The analog signal amplified by the signal amplifier circuit 102 is converted into a suitable frequency for subsequent processing by the frequency conversion circuit 103. A noise component of the analog signal having the frequency converted by the frequency conversion circuit 103 is removed by the filter circuit 104. A lowpass filter, a highpass filter, a bandpass filter, an integration circuit, and the like can be used as the filter circuit 104.

The analog signal in which the noise component has been removed by the filter circuit 104 is input to the A/D converter 100. The A/D converter 100 is the A/D converter according to the fifth embodiment. The A/D converter 100 converts the analog signal A_{IN} input from the filter circuit 104 to a digital signal D_{OUT} by the above-mentioned processing and outputs the converted signal. The digital signal processor 105 executes various digital signal processing based on the digital signal Dour input from the A/D converter 100.

According to the present embodiment, a low power consumption communication apparatus which can operate at high speed can be configured. In the above description, the operation of the communication apparatus for receiving the signal has been described. However, the communication apparatus may include a function to transmit the signal.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An amplifier circuit comprising:
an input terminal;
an output terminal;
an amplifier, in which an input side is connected to the input terminal and an output side is connected to the output terminal, to amplify a difference between a signal input from the input side and a predetermined reference signal with a predetermined gain;
a first switch to open and close between the output side of the amplifier and the output terminal; and
a first signal setter to set the signal of the output terminal to a predetermined signal when the first switch opens.

2. The amplifier circuit according to claim 1, wherein
the first signal setter includes
a first signal source to be connected to the output terminal and output a first signal to the output terminal and
a second switch to open and close between the first signal source and the output terminal.

3. The amplifier circuit according to claim 1, further comprising:
a second signal setter to set a signal of the output side of the amplifier to a predetermined signal when the first switch opens.

4. The amplifier circuit according to claim 3, wherein
the second signal setter includes
a second signal source to be connected to the output side of the amplifier and output a second signal to the output side of the amplifier and
a third switch to open and close between the second signal source and the output side of the amplifier.

5. The amplifier circuit according to claim 3, wherein
the second signal setter includes
a third signal source to be connected to an input side of the amplifier and output a third signal to the input side of the amplifier and
a fourth switch to open and close between the third signal source and the input side of the amplifier.

6. The amplifier circuit according to claim 5, wherein
the first and third signal sources are shared, and the amplifier is a reversed-phase amplifier.

7. The amplifier circuit according to claim 3, wherein
the amplifier is a differential amplifier for amplifying a difference between two signals input from the input side with a predetermined gain; and
the second signal setter includes
a fourth signal source to be connected to one line of the input side of the amplifier and output a fourth signal to the one line of the input side of the amplifier,
a fifth switch to open and close between the fourth signal source and the one line of the input side of the amplifier,
a fifth signal source to be connected to another line of the input side of the amplifier and output a fifth signal to the another line of the input side of the amplifier, and
a sixth switch to open and close between the fifth signal source and the another line of the input side of the amplifier.

8. The amplifier circuit according to claim 7, wherein
the first signal setter includes
a sixth signal source to be connected to one line of the output terminal and output a sixth signal to the one line of the output terminal,
a seventh switch to open and close between the sixth signal source and the one line of the output terminal,
a seventh signal source to be connected to another line of the output terminal and output a seventh signal to the another line of the output terminal, and
an eighth switch to open and close between the seventh signal source and the another line of the output terminal.

9. An A/D converter comprising the amplifier circuit according to claim 1.

10. A communication apparatus comprising the A/D converter according to claim 9.
